(19) United States
(12) Patent Application Publication
(10) Pub. No.: US 2024/0355927 A1
(43) Pub. Date: Oct. 24, 2024

(54) SEMICONDUCTOR DEVICE STRUCTURE WITH EXPANSION FILM AND METHOD FOR FORMING THE SAME

(71) Applicant: Taiwan Semiconductor Manufacturing Company, Ltd., Hsinchu (TW)

(72) Inventors: Szu-Ying CHEN, Hsinchu (TW); Sen-Hong SYUE, Zhubei City (TW); Chi On CHUI, Hsinchu City (TW)

(21) Appl. No.: 18/305,514

(22) Filed: Apr. 24, 2023

(51) Int. Cl. H01L 29/78; H01L 21/8238; H01L 27/092; H01L 29/66

(52) U.S. Cl. CPC H01L 29/7851; H01L 21/823821; H01L 27/0924; H01L 29/66795; H01L 2029/7858

(57) ABSTRACT

A method for forming a semiconductor device structure is provided. The method includes forming an expansion film over a substrate. The substrate has a base portion, a first fin, and a second fin over the base portion. The method includes forming an isolation layer over the expansion film. The method includes annealing the expansion film, the substrate, and the isolation layer. The method includes partially removing the isolation layer and the expansion film to expose the first upper portion of the first fin and the second upper portion of the second fin. The method includes forming a gate stack wrapping around the first upper portion of the first fin and the second upper portion of the second fin.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1G are cross-sectional views of various stages of a process for forming a semiconductor device structure, in accordance with some embodiments.

FIG. 1F-1 is a top view of the semiconductor device structure of FIG. 1F, in accordance with some embodiments.

FIG. 1G-1 is a top view of the semiconductor device structure of FIG. 1G, in accordance with some embodiments.

FIGS. 2A-2D are cross-sectional views of various stages of a process for forming a semiconductor device structure, in accordance with some embodiments.

FIG. 2B-1 is a top view of the semiconductor device structure of FIG. 2B, in accordance with some embodiments.

FIG. 2C-1 is a top view of the semiconductor device structure of FIG. 2C, in accordance with some embodiments.

FIG. 2D-1 is a top view of the semiconductor device structure of FIG. 2D, in accordance with some embodiments.

FIG. 2D-2 is a cross-sectional view illustrating the semiconductor device structure along a sectional line II-II′ in FIG. 2D-1, in accordance with some embodiments.

FIGS. 3A-3C are cross-sectional views of various stages of a process for forming a semiconductor device structure, in accordance with some embodiments.

FIG. 3C-1 is a top view of the semiconductor device structure of FIG. 3C, in accordance with some embodiments.

FIG. 3C-2 is a cross-sectional view illustrating the semiconductor device structure along a sectional line II-II′ in FIG. 3C-1, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain structure(s) may refer to a source or a drain, individually or collectively dependent upon the context.

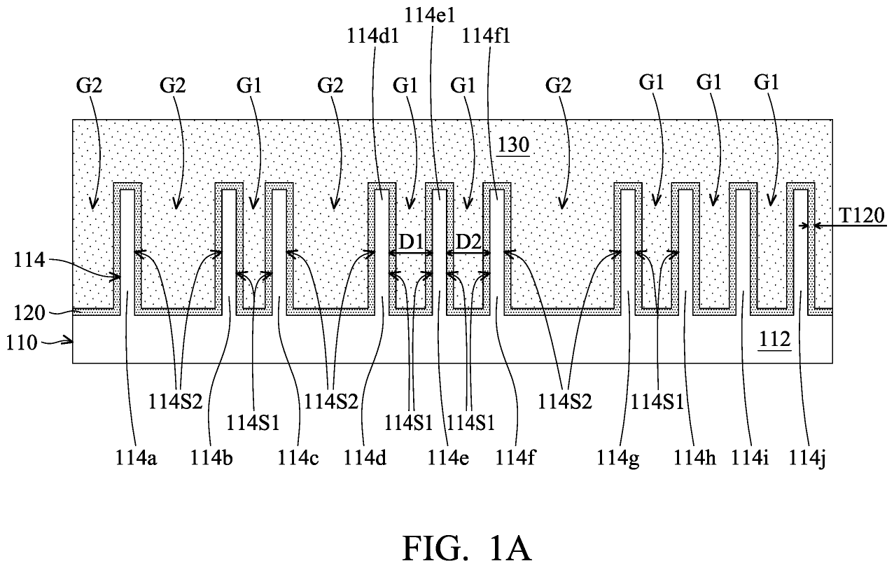

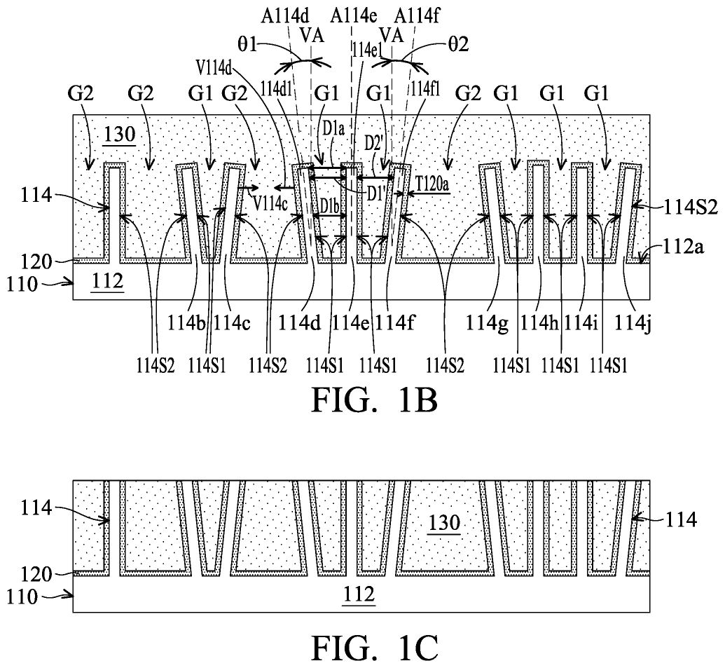

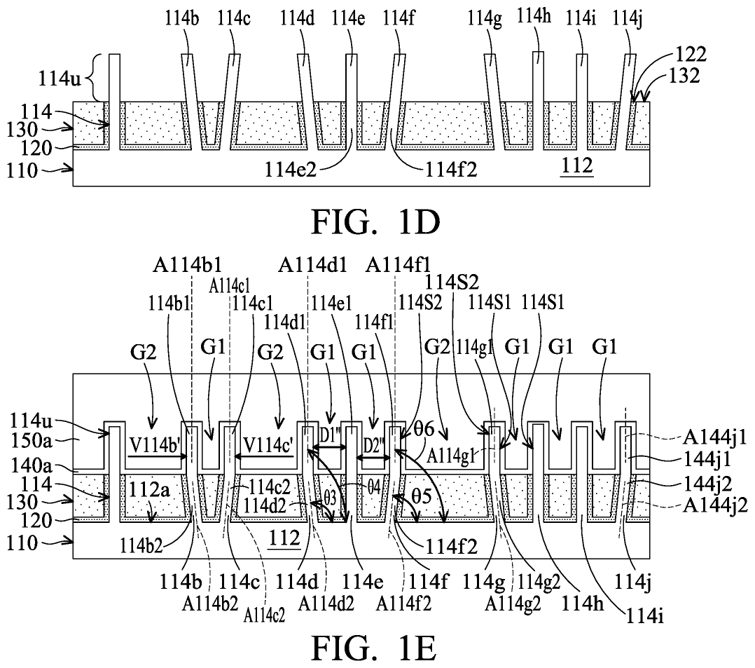

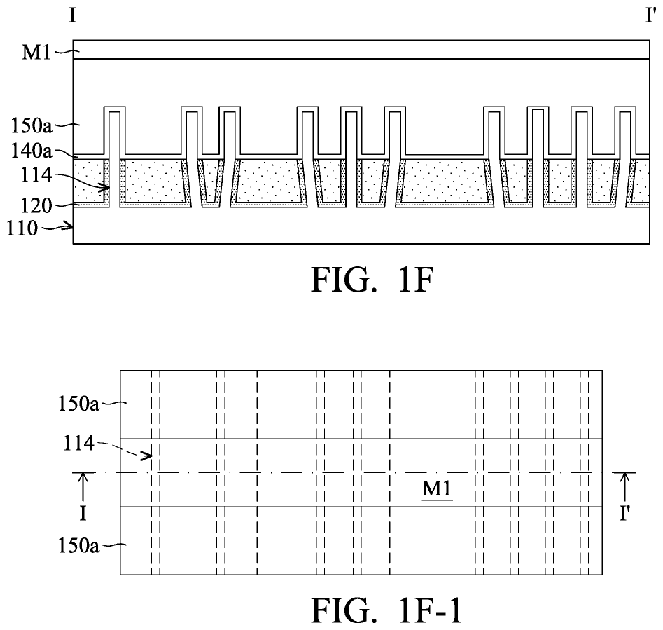

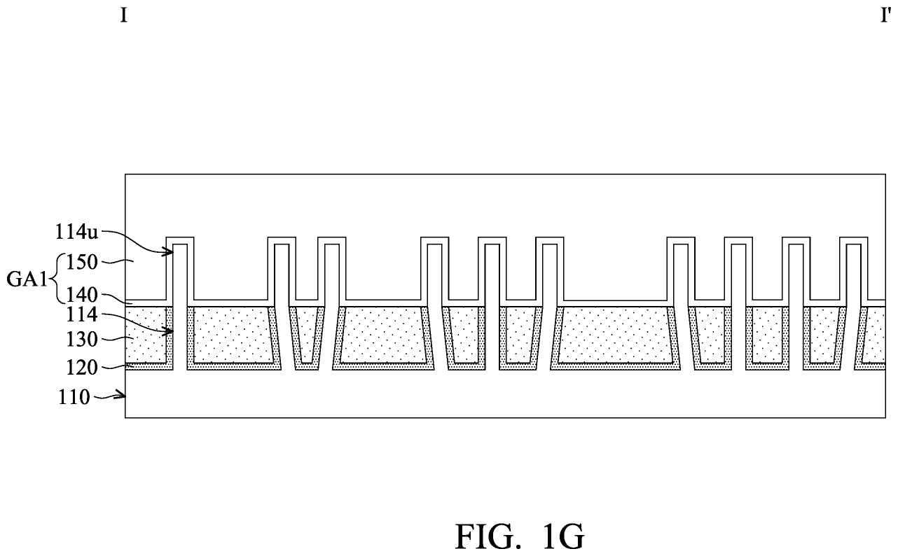

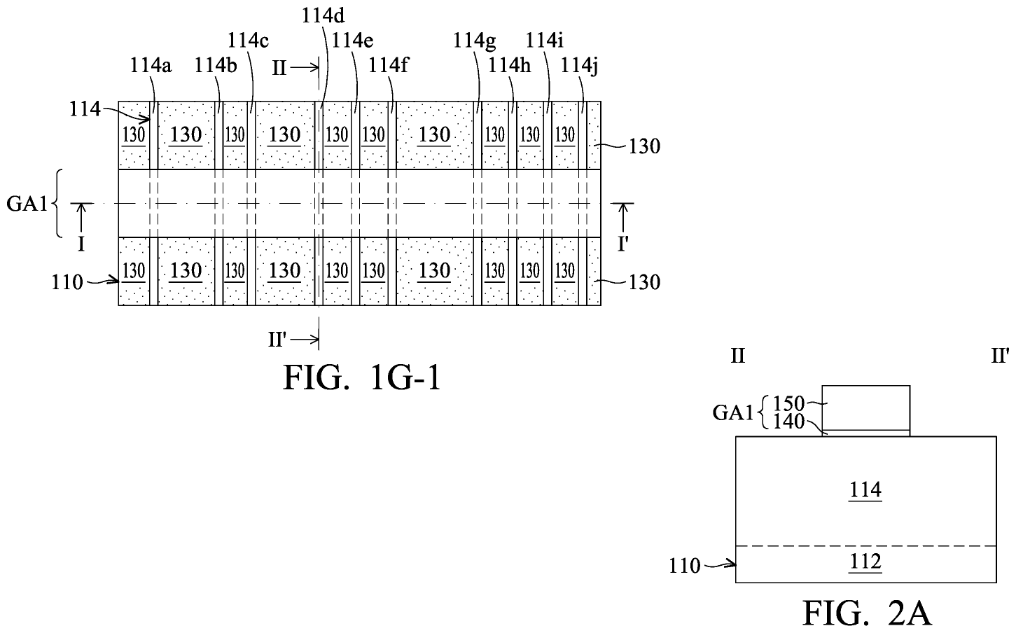

FIGS. 1A-1G are cross-sectional views of various stages of a process for forming a semiconductor device structure, in accordance with some embodiments. As shown in FIG. 1A, a substrate 110 is provided, in accordance with some embodiments. The substrate 110 has a base portion 112 and fins 114 over the base portion 112, in accordance with some embodiments. The fins 114 include fins 114a, 114b, 114c, 114d, 114e, 114f, 114g, 114h, 114i, and 114j, in accordance with some embodiments.

The fins 114b and 114c are spaced apart from each other by a narrow gap G1, in accordance with some embodiments. The fins 114d, 114e, and 114f are spaced apart from each other by narrow gaps G1, in accordance with some embodiments. The fins 114g, 114h, 114i, and 114j are spaced apart from each other by narrow gaps G1, in accordance with some embodiments.

In some embodiments, an average distance D1 is between an upper portion 114d1 of the fin 114d and an upper portion 114el of the fin 114e. The average distance D1 ranges from about 20 nm to about 40 nm, in accordance with some embodiments. In some embodiments, an average distance D2 is between the upper portion 114el of the fin 114e and an upper portion 114f1 of the fin 114f. The average distance D2 ranges from about 20 nm to about 40 nm, in accordance with some embodiments.

The fins 114a and 114b are spaced apart from each other by a wide gap G2, in accordance with some embodiments. The fins 114c and 114d are spaced apart from each other by a wide gap G2, in accordance with some embodiments. The fins 114f and 114g are spaced apart from each other by a wide gap G2, in accordance with some embodiments.

The wide gap G2 is wider than the narrow gap G1, in accordance with some embodiments. The fins 114 have sidewalls 114s1 and 114s2, in accordance with some embodiments. The sidewalls 114s1 face the narrow gap G1, in accordance with some embodiments. The sidewalls 114s2 face the wide gap G2, in accordance with some embodiments.

The substrate 110 includes, for example, a semiconductor substrate. The substrate 110 includes, for example, a semiconductor wafer (such as a silicon wafer) or a portion of a semiconductor wafer. In some embodiments, the substrate 110 is made of an elementary semiconductor material including silicon or germanium in a single crystal structure, a polycrystal structure, or an amorphous structure.

In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIG. 1A, an expansion film 120 is formed over the substrate 110, in accordance with some embodiments. The expansion film 120 conformally covers the base portion 112 and the fins 114, in accordance with some embodiments. The expansion film 120 has an average thickness T120 ranging from about 30 Å to about 60 Å, in accordance with some embodiments.

The expansion film 120 is made of a thermal-expansion insulating material, such as a nitrogen-containing material (e.g., SiON or SiCN) or a carbon-containing material (e.g., SiOC or SiCON), or silicon, in accordance with some embodiments. The expansion film 120 is formed using a deposition process such as a chemical vapor deposition (CVD) process or an atomic layer deposition (ALD) process, in accordance with some embodiments.

As shown in FIG. 1A, an isolation layer 130 is formed over the expansion film 120, in accordance with some embodiments. In some embodiments, a density of the expansion film 120 is greater than a density of the isolation layer 130. The isolation layer 130 includes oxide (such as silicon oxide, SiON, or SiONH), in accordance with some embodiments.

The isolation layer 130 is formed by a chemical vapor deposition (CVD) process such as a flowable chemical vapor deposition (FCVD) process, in accordance with some embodiments. The isolation layer 130 and the expansion film 120 are formed using different deposition processes, in accordance with some embodiments.

As shown in FIG. 1B, an annealing process is performed on the expansion film 120, the substrate 110, and the isolation layer 130, in accordance with some embodiments. After the annealing process, the expansion film 120 expands and provides compressive stress to the sidewalls 114s1 and 114s2 of the fins 114, in accordance with some embodiments.

Since the narrow gap G1 is narrower than the wide gap G2, the compressive stress applied to the sidewalls 114s1 facing the narrow gap G1 is greater than the compressive stress applied to the sidewalls 114s2 facing the wide gap G2, in accordance with some embodiments. Therefore, a central axis A114d of the fin 114d rotates in a direction V114d away from the adjacent narrow gap G1 (or the adjacent fin, i.e., the fin 114e), in accordance with some embodiments.

In the application, the central axis may also be referred to as a center line, a middle line, or a symmetry line, in accordance with some embodiments. A first distance between the central axis and a left sidewall of the corresponding fin is equal to a second distance between the central axis and a right sidewall of the corresponding fin, in accordance with some embodiments.

Similarly, central axes of the fins 114b and 114g also rotate in the direction V114d away from the adjacent narrow gap G1 (or toward the adjacent wide gap G2), and the central axes of the fins 114c, 114f, and 114j rotate in the direction V114c away from the adjacent narrow gap G1 (or toward the adjacent wide gap G2), in accordance with some embodiments.

As shown in FIGS. 1A and 1B, after the annealing process, the expansion film 120 has an average thickness T120a, in accordance with some embodiments. The average thickness T120a is greater than the average thickness T120 of the expansion film 120 before the annealing process, in accordance with some embodiments. In some embodiments, a ratio of the average thickness T120a to the average thickness T120 is greater than or equal to 1.05.

When the film 120 is made of silicon, the ratio of the average thickness T120a to the average thickness T120 ranges from about 2 to about 2.5, in accordance with some embodiments. The density of the expansion film 120 before the annealing process is greater than the density of the expansion film 120 after the annealing process, in accordance with some embodiments.

As shown in FIGS. 1A and 1B, after the annealing process, an average distance D1′ is between the upper portion 114d1 of the fin 114d and the upper portion 114el of the fin 114e, and an average distance D2′ is between the upper portion 114el of the fin 114e and the upper portion 114f1 of the fin 114f, in accordance with some embodiments.

The average distance D1′ is greater than the average distance D1 between the upper portion 114d1 of the fin 114d and the upper portion 114el of the fin 114e before the annealing process, in accordance with some embodiments. The average distance D2′ is greater than the average distance D2 between the upper portion 114e1 of the fin 114e and the upper portion 114f1 of the fin 114f before the annealing process, in accordance with some embodiments.

As shown in FIG. 1B, after the annealing process, a distance D1a between top ends of the fins 114d and 114e is greater than a distance D1b between middle portions of the fins 114d and 114e, in accordance with some embodiments. In some embodiments, a difference between the distances D1a and D1b is greater than 0.49 nm.

The difference between the distances D1a and D1b ranges from about 0.5 nm to about 2 nm, in accordance with some embodiments. In some embodiments, a distance between the fins 114d and 114e continuously decreases from the top ends of the fins 114d and 114e to the base portion 112.

As shown in FIG. 1B, after the annealing process, the central axis A114d of the fin 114d is not parallel to a central axis A114e of the fin 114e, in accordance with some embodiments. After the annealing process, the central axis A114e of the fin 114e is steeper than the central axis A114d of the fin 114d and the central axis A114f of the fin 114f, in accordance with some embodiments.

After the annealing process, an angle θ1 between the central axis A114d of the fin 114d and a vertical axis VA, which is perpendicular to a top surface 112a of the base portion 112, ranges from about 1° to about 5°, in accordance with some embodiments. In some embodiments, an angle θ2 between the central axis A114f of the fin 114f and the vertical axis VA ranges from about 1° to about 5°, in accordance with some embodiments.

The annealing process includes a plasma oxidation process, in accordance with some embodiments. The expansion film 120 is oxidized after the annealing process, in accordance with some embodiments. The oxidant of the plasma oxidation process includes H₂O₂, H₂O, O₂, O₃, and an oxygen radical, in accordance with some embodiments.

In some embodiments, the annealing process includes a wet steam annealing process. The steam used by the annealing process includes H₂O, in accordance with some embodiments. The steam can be generated by oxyhydrogen flame (H₂ and O₂), H₂O vaporizer, or catalytic conversion (H₂ and O₂), in accordance with some embodiments.

The process temperature of the annealing process ranges from about 300° C. to about 700° C., in accordance with some embodiments. The annealing time ranges from about 10 minutes to about 8 hours, in accordance with some embodiments. The process pressure ranges from about 2 torr to about 20 atm, in accordance with some embodiments.

The annealing process can decrease the nitrogen concentration of the film 120, which improves the electrical insulating property of the film 120, in accordance with some embodiments. That is, the nitrogen concentration of the film 120 after the annealing process is lower than the nitrogen concentration of the film 120 before the annealing process, in accordance with some embodiments.

The nitrogen atoms in the film 120 are replaced by oxygen atoms during the annealing process, in accordance with some embodiments. The nitrogen concentration of the film 120 after the annealing process is less than 1 at %, in accordance with some embodiments.

As shown in FIG. 1C, a thinning process is performed on the isolation layer 130 until the fins 114 are exposed, in accordance with some embodiments. The upper portions of the isolation layer 130, the expansion film 120, and the fins 114 are removed, in accordance with some embodiments. The thinning process includes a planarization process such as a chemical mechanical polishing (CMP) process, in accordance with some embodiments.

As shown in FIG. 1D, upper portion of the isolation layer 130 and the expansion film 120 are removed to expose upper portions 114u of the fins 114, in accordance with some embodiments. In some embodiments, a top surface 122 of the expansion film 120 is substantially level with a top surface 132 of the isolation layer 130.

As shown in FIG. 1E, a gate dielectric material layer 140a is formed over the upper portions of the fins 114, the expansion film 120, and the isolation layer 130, in accordance with some embodiments. The gate dielectric material layer 140a is made of oxides such as silicon oxide, in accordance with some embodiments. The gate dielectric material layer 140a is formed using a chemical vapor deposition process (CVD process), in accordance with some embodiments.

As shown in FIG. 1E, a gate electrode layer 150a is formed over the gate dielectric material layer 140a, in accordance with some embodiments. The gate electrode layer 150a is made of a semiconductor material such as polysilicon, in accordance with some embodiments. The gate electrode layer 150a is formed using a chemical vapor deposition process, in accordance with some embodiments.

Since the gate electrode layer 150a may provide a tensile stress to the sidewalls 114s1 and 114s2 of the fins 114 and the narrow gap G1 is filled up before the wide gap G2 is filled up, the tensile stress applied to the sidewalls 114s1 may be greater than the tensile stress applied to the sidewalls 114s2.

Therefore, the central axes A114b1, A114d1, and A114g1 of the upper portions 114b1, 114d1, and 114g1 of the fins 114b, 114d, and 114g rotate in the direction V114b′ toward the adjacent narrow gap G1 (or away from the adjacent wide gap G2), in accordance with some embodiments.

The central axes A114c1, A114f1, and A114j1 of the upper portions 114c1, 114f1, and 114j1 of the fins 114c, 114f, and 114j rotate in the direction V114c′ toward the adjacent narrow gap G1 (or away from the adjacent wide gap G2), in accordance with some embodiments.

As shown in FIGS. 1B and 1E, a distance D1″ between the upper portion 114d1 of the fin 114d and the upper portion 114el of the fin 114e after the gate electrode layer 150a is formed is less than the average distance D1′ between the upper portion 114d1 of the fin 114d and the upper portion 114el of the fin 114e after the annealing process and before the gate electrode layer 150a is formed, in accordance with some embodiments.

After the gate electrode layer 150a is formed, the central axes A114b1, A114c1, A114d1, A114f1, A114g1, and A114j1 are substantially parallel to each other, in accordance with some embodiments. The central axis A114b1 of the upper portion 114b1 of the fin 114b is not parallel to the central axis A114b2 of the lower portion 114b2 of the fin 114b, in accordance with some embodiments.

The central axis A114cl of the upper portion 114cl of the fin 114c is not parallel to the central axis A114c2 of the lower portion 114c2 of the fin 114c, in accordance with some embodiments. The central axis A114d1 of the upper portion 114d1 of the fin 114d is not parallel to the central axis A114d2 of the lower portion 114d2 of the fin 114d, in accordance with some embodiments.

The central axis A114f1 of the upper portion 114f1 of the fin 114f is not parallel to the central axis A114f2 of the lower portion 114f2 of the fin 114f, in accordance with some embodiments. The central axis A114g1 of the upper portion 114g1 of the fin 114g is not parallel to the central axis A114g2 of the lower portion 114g2 of the fin 114g, in accordance with some embodiments.

The central axis A114j1 of the upper portion 114j1 of the fin 114j is not parallel to the central axis A114j2 of the lower portion 114j2 of the fin 114j, in accordance with some embodiments. The central axes A114b1, A114c1, A114d1, A114f1, A114g1, and A114j1 are steeper than the central axes A114b2, A114c2, A114d2, A114f2, A114g2, and A114j2, in accordance with some embodiments.

In some embodiments, an angle θ3 between the central axis A114d2 of the lower portion 114d2 and the top surface 112a of the base portion 112 is greater than 90°. In some embodiments, an angle θ4 between the central axis A114d1 of the upper portion 114d1 and the top surface 112a of the base portion 112 is about 90°.

In some embodiments, an angle θ5 between the central axis A114f2 of the lower portion 114f2 and the top surface 112a of the base portion 112 is less than 90°. In some embodiments, an angle θ6 between the central axis A114f1 of the upper portion 114f1 and the top surface 112a of the base portion 112 is about 90°.

The expansion film 120 and the annealing process increase the distance between the upper portions 114u of the fins 114, which prevents the distance between the upper portions 114u of the fins 114 from becoming too small after the gate electrode layer 150a is formed, in accordance with some embodiments.

Therefore, the expansion film 120 and the annealing process facilitate in forming a metal gate stack, which fills the narrow gaps G1 and the wide gaps G2 between the fins 114, in a subsequent process, in accordance with some embodiments. As a result, the expansion film 120 and the annealing process improve the yield performance of the semiconductor device structure, in accordance with some embodiments.

FIG. 1F-1 is a top view of the semiconductor device structure of FIG. 1F, in accordance with some embodiments. FIG. 1F is a cross-sectional view illustrating the semiconductor device structure along a sectional line I-I′ in FIG. 1F-1, in accordance with some embodiments.

As shown in FIGS. 1F and 1F-1, a mask layer M1 is formed over the gate electrode layer 150a, in accordance with some embodiments. The mask layer M1 and the gate electrode layer 150a are made of different materials, in accordance with some embodiments. The mask layer M1 is made of a polymer material (e.g., a photoresist material) or a nitrogen-containing material (e.g., silicon nitride), in accordance with some embodiments.

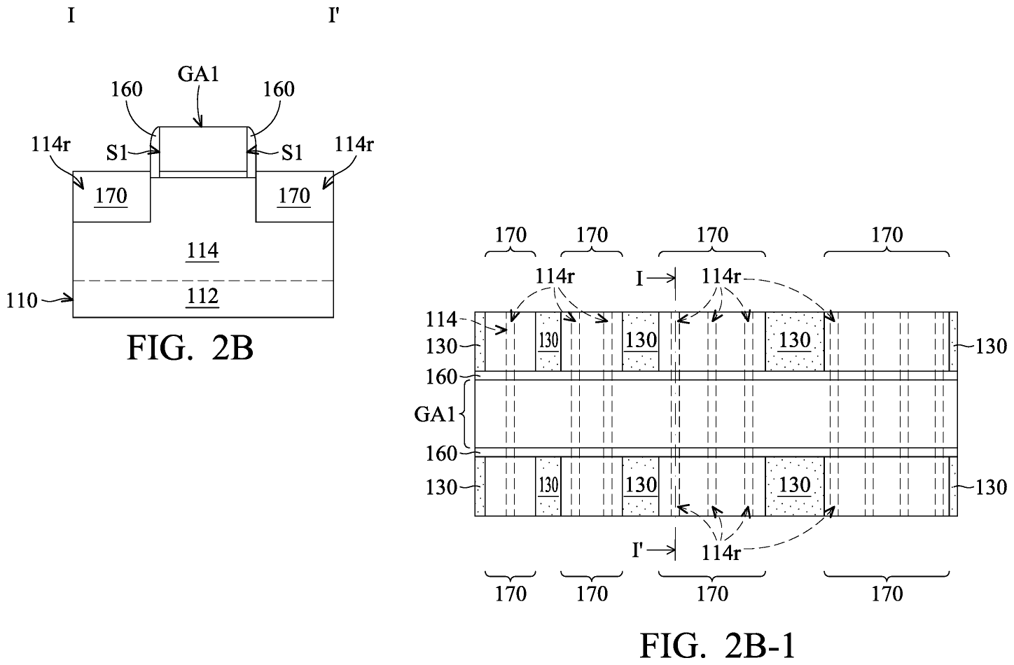

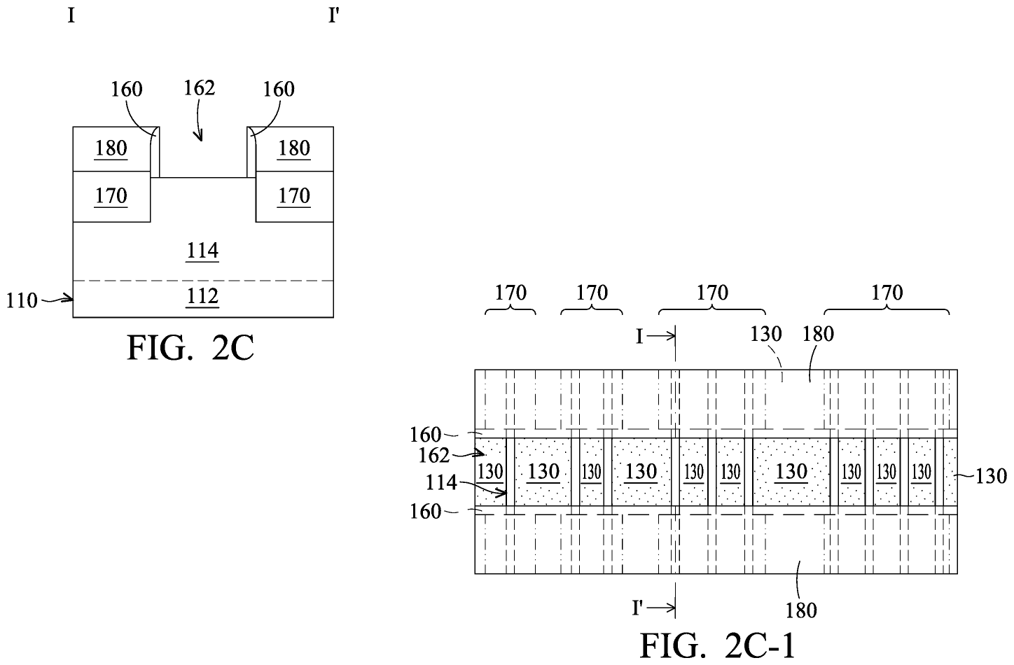

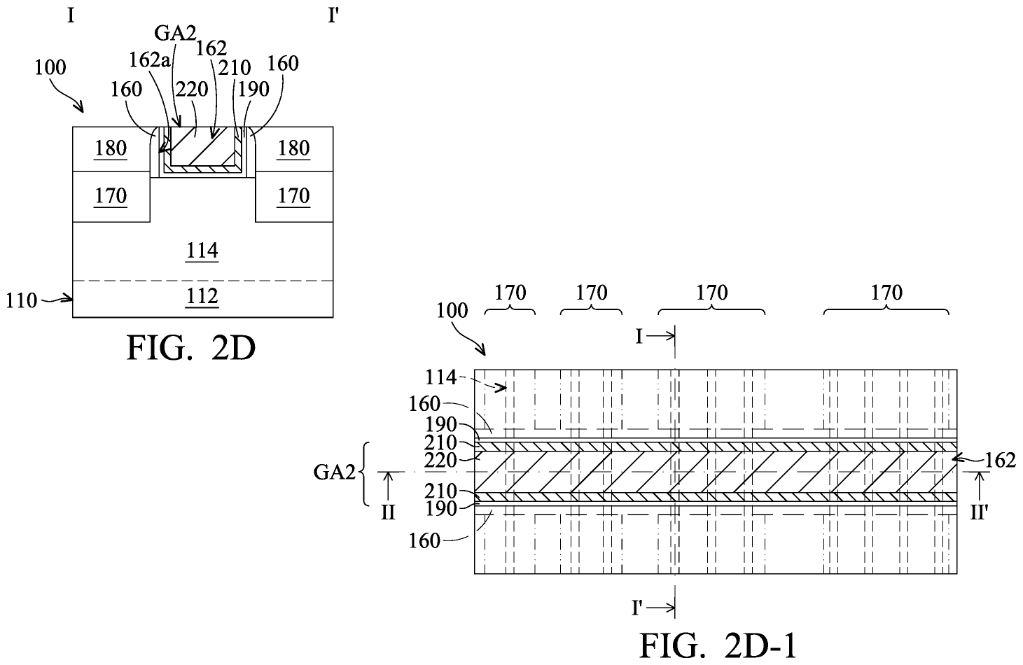

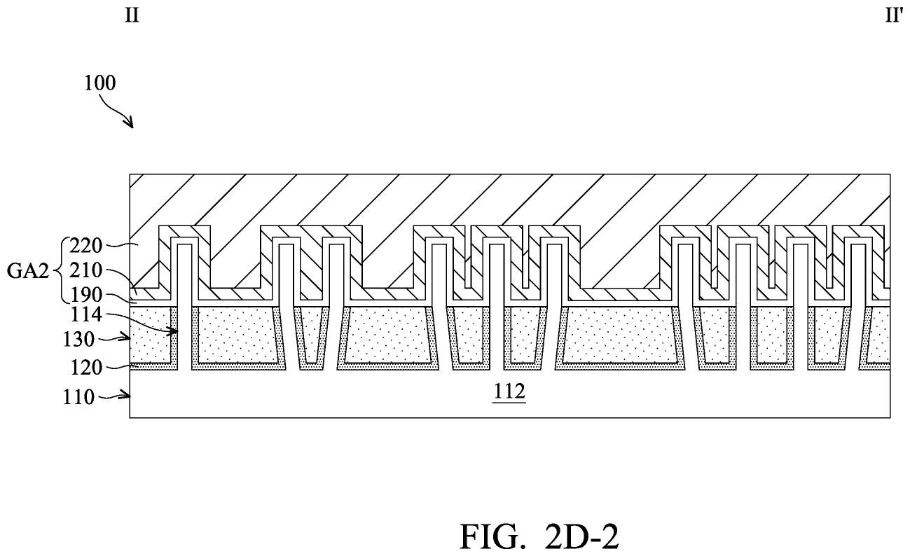

FIG. 1G-1 is a top view of the semiconductor device structure of FIG. 1G, in accordance with some embodiments. FIG. 1G is a cross-sectional view illustrating the semiconductor device structure along a sectional line I-I′ in FIG. 1G-1, in accordance with some embodiments. FIG. 2A is a cross-sectional view illustrating the semiconductor device structure along a sectional line II-II′ in FIG. 1G-1, in accordance with some embodiments.

As shown in FIGS. 1F-1, 1G, 1G-1, and 2A, portions of the gate electrode layer 150a, which are not covered by the mask layer M1, are removed, in accordance with some embodiments. As shown in FIGS. 1F-1, 1G, 1G-1, and 2A, portions of the gate dielectric material layer 140a originally under the removed portions of the gate electrode layer 150a are removed, in accordance with some embodiments.

The remaining portion of the gate electrode layer 150a forms a gate electrode 150, and the remaining portion of the gate dielectric material layer 140a forms a gate dielectric layer 140, in accordance with some embodiments. The gate electrode 150 and the gate dielectric layer 140 together form a gate stack GA1, in accordance with some embodiments. The gate stack GA1 wraps around the upper portions 114u of the fins 114, in accordance with some embodiments. As shown in FIGS. 1G, 1G-1, and 2A, the mask layer M1 is removed, in accordance with some embodiments.

FIGS. 2A-2D are cross-sectional views of various stages of a process for is formed a semiconductor device structure, in accordance with some embodiments. FIG. 2B-1 is a top view of the semiconductor device structure of FIG. 2B, in accordance with some embodiments. FIG. 2B is a cross-sectional view illustrating the semiconductor device structure along a sectional line I-I′ in FIG. 2B-1, in accordance with some embodiments.

As shown in FIGS. 2B and 2B-1, a spacer layer 160 is formed over sidewalls S1 of the gate stack GA1, in accordance with some embodiments. The spacer layer 160 surrounds the gate stack GA1, in accordance with some embodiments. The spacer layer 160 is positioned over the fins 114 and the isolation layer 130, in accordance with some embodiments.

The spacer layer 160 includes insulating materials, such as silicon oxide, silicon nitride, silicon oxynitride, or silicon carbide, in accordance with some embodiments. The formation of the spacer layer 160 includes a deposition process and an anisotropic etching process, in accordance with some embodiments.

As shown in FIGS. 2B and 2B-1, portions of the fins 114, which are not covered by the gate stack GA1 and the spacer layer 160, are removed, in accordance with some embodiments. The removal process forms recesses 114r in the fins 114 respectively, in accordance with some embodiments. The removal process includes an etching process such as a dry etching process, in accordance with some embodiments.

As shown in FIGS. 2B and 2B-1, source/drain structures 170 are formed in the recesses 114r of the fins 114, in accordance with some embodiments. The source/drain structures 170 are in direct contact with the fins 114 thereunder, in accordance with some embodiments. The source/drain structures 170 are positioned on two opposite sides of the gate stack GA1, in accordance with some embodiments.

The source/drain structures 170 are made of an N-type conductivity material, in accordance with some embodiments. The N-type conductivity material includes silicon phosphorus (SiP) or another suitable N-type conductivity material. The source/drain structures 170 are formed using an epitaxial process, in accordance with some embodiments.

The source/drain structures 170 are doped with the Group VA element, in accordance with some embodiments. The Group VA element includes phosphor (P), antimony (Sb), or another suitable Group VA material. In some embodiments, a concentration of the Group VA element (e.g. phosphor) ranges from about 3E21 atoms/cm³ to about 7E21 atoms/cm³. The source/drain structures 170 are also referred to as doped structures, in accordance with some embodiments.

In some other embodiments, the source/drain structures 170 are made of a P-type conductivity material, in accordance with some embodiments. The P-type conductivity material includes silicon germanium (SiGe) or another suitable P-type conductivity material.

The source/drain structures 170 are formed using an epitaxial process, in accordance with some embodiments. The source/drain structures 170 are doped with the Group IIIA element, in accordance with some embodiments. The Group IIIA element includes boron or another suitable material.

An etch stop layer (not shown) is conformally formed over the spacer layer 160, the isolation layer 130, and the source/drain structures 170, in accordance with some embodiments. The etch stop layer is made of an insulating material, such as a nitrogen-containing material (e.g., silicon nitride), in accordance with some embodiments.

The etch stop layer is formed using a deposition process, such as a chemical vapor deposition (CVD) process, an atomic layer deposition (ALD) process, or a physical vapor deposition (PVD) process, in accordance with some embodiments. In some embodiments (e.g., FIG. 2C), the etch stop layer is not formed.

FIG. 2C-1 is a top view of the semiconductor device structure of FIG. 2C, in accordance with some embodiments. FIG. 2C is a cross-sectional view illustrating the semiconductor device structure along a sectional line I-I′ in FIG. 2C-1, in accordance with some embodiments.

As shown in FIGS. 2C and 2C-1, a dielectric layer 180 is formed over the etch stop layer or over the spacer layer 160, the isolation layer 130, and the source/drain structures 170, in accordance with some embodiments. The dielectric layer 180 is made of any suitable insulating material, such as silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof.

The dielectric layer 180 is formed by a deposition process, such as a chemical vapor deposition (CVD) process, an atomic layer deposition (ALD) process, or a physical vapor deposition (PVD) process, in accordance with some embodiments.

As shown in FIGS. 2C and 2C-1, the gate stack GA1 is removed, in accordance with some embodiments. The removal process includes a wet etching process, in accordance with some embodiments. After the removal process, a trench 162 is formed in the spacer layer 160, in accordance with some embodiments. The trench 162 exposes portions of the fins 114, in accordance with some embodiments.

FIG. 2D-1 is a top view of the semiconductor device structure of FIG. 2D, in accordance with some embodiments. FIG. 2D is a cross-sectional view illustrating the semiconductor device structure along a sectional line I-I′ in FIG. 2D-1, in accordance with some embodiments. FIG. 2D-2 is a cross-sectional view illustrating the semiconductor device structure along a sectional line II-II′ in FIG. 2D-1, in accordance with some embodiments.

As shown in FIGS. 2D, 2D-1, and 2D-2, a gate stack GA2 are formed in the trench 162 of the spacer layer 160, in accordance with some embodiments. As shown in FIGS. 2D, 2D-1, and 2D-2, the gate stack GA2 includes a gate dielectric layer 190, a work function metal layer 210, and a gate electrode 220, in accordance with some embodiments. The gate dielectric layer 190 conformally covers the inner walls 162a of the trench 162 and the fins 114 exposed by the trench 162, in accordance with some embodiments.

The work function metal layer 210 is formed over the gate dielectric layer 190, in accordance with some embodiments. The work function metal layer 210 conformally covers the gate dielectric layer 190, in accordance with some embodiments. The gate electrode 220 is formed over the work function metal layer 210 to fill the trench 162, in accordance with some embodiments.

The gate dielectric layer 190 is made of an insulating material such as silicon oxide, silicon nitride, silicon oxynitride, a dielectric material with high dielectric constant (high-K), another suitable dielectric material, or a combination thereof.

Examples of high-K dielectric materials include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof.

The gate dielectric layer 190 is formed using a deposition process and a planarization process, in accordance with some embodiments. The deposition process includes a physical vapor deposition (PVD) process, a CVD process, an atomic layer deposition (ALD), another suitable method, or a combination thereof.

The work function metal layer 210 provides a desired work function for transistors to enhance device performance including improved threshold voltage. In the embodiments of forming an NMOS transistor, the work function metal layer 210 can be an n-type metal capable of providing a work function value suitable for the device, such as equal to or less than about 4.5 eV.

The n-type metal may be made of metal, metal carbide, metal nitride, or a combination thereof. For example, the n-type metal is made of tantalum, tantalum nitride, or a combination thereof.

In the embodiments of forming a PMOS transistor, the work function metal layer 210 can be a p-type metal capable of providing a work function value suitable for the device, such as equal to or greater than about 4.8 eV. The p-type metal may be made of metal, metal carbide, metal nitride, other suitable materials, or a combination thereof.

For example, the p-type metal is made of titanium, titanium nitride, other suitable materials, or a combination thereof. The work function metal layer 210 is formed using a deposition process and a planarization process, in accordance with some embodiments. The deposition process includes a physical vapor deposition (PVD) process, a CVD process, an atomic layer deposition (ALD), a plating process, another suitable method, or a combination thereof.

The gate electrode 220 is made of a suitable metal material, such as aluminum, tungsten, gold, platinum, cobalt, another suitable metal, an alloy thereof, or a combination thereof, in accordance with some embodiments. The gate electrode 220 is formed using a deposition process and a planarization process, in accordance with some embodiments.

The deposition process includes a physical vapor deposition (PVD) process, a CVD process, an atomic layer deposition (ALD), a plating process, another suitable method, or a combination thereof. In this step, a semiconductor device structure 100 is substantially formed, in accordance with some embodiments.

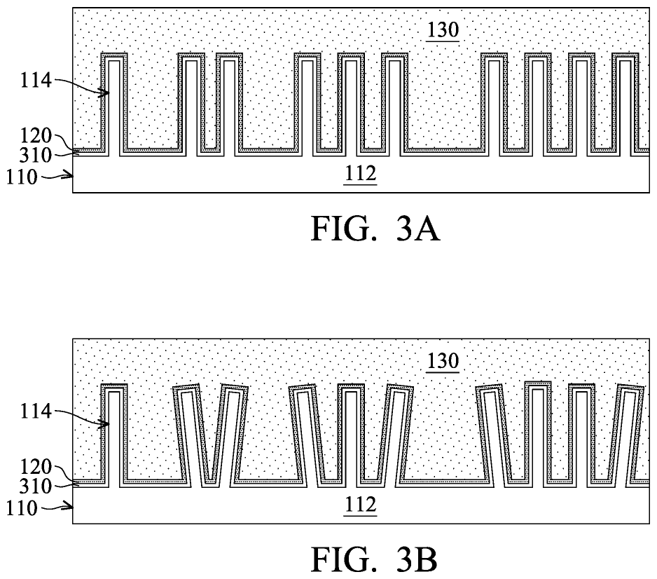

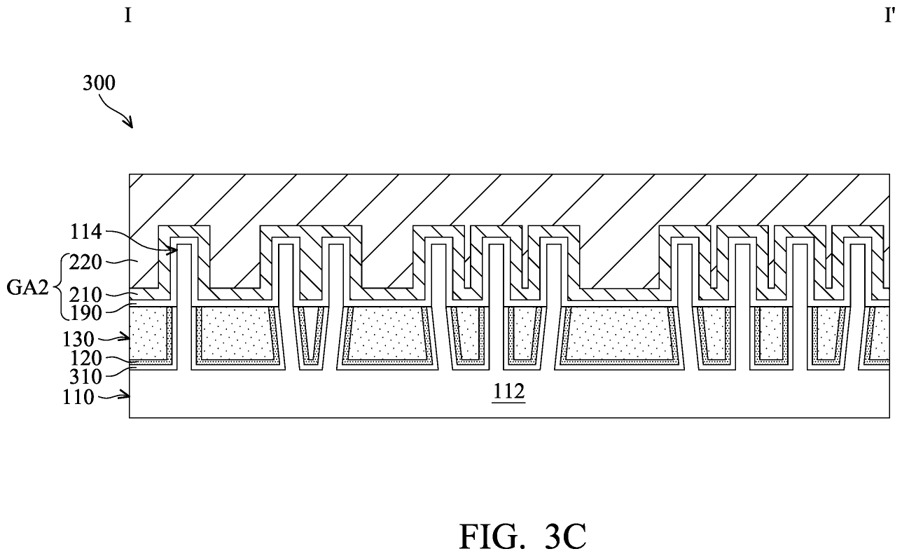

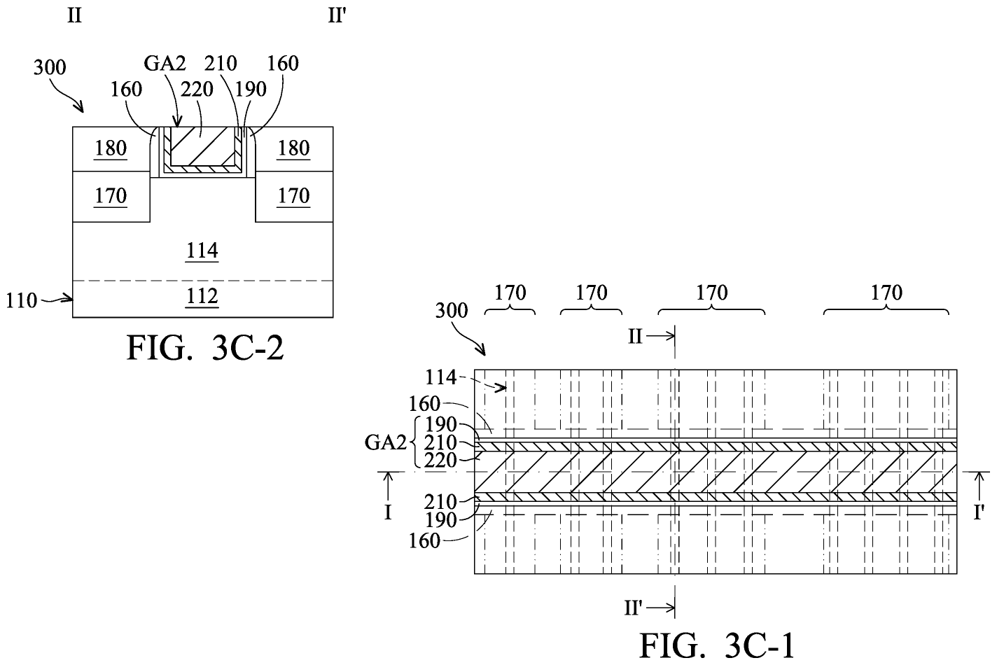

FIGS. 3A-3C are cross-sectional views of various stages of a process for is formed a semiconductor device structure, in accordance with some embodiments. As shown in FIG. 3A, the step of FIG. 1A is performed, and a liner layer 310 is formed over the substrate 110 before the expansion film 120 is formed over the substrate 110, in accordance with some embodiments.

The expansion film 120 is formed over the liner layer 310, in accordance with some embodiments. The liner layer 310 and the expansion film 120 are made of different materials, in accordance with some embodiments. The liner layer 310 is made of an oxide material such as silicon oxide, in accordance with some embodiments. As shown in FIG. 3B, the step of FIG. 1B is performed, in accordance with some embodiments.

FIG. 3C-1 is a top view of the semiconductor device structure of FIG. 3C, in accordance with some embodiments. FIG. 3C is a cross-sectional view illustrating the semiconductor device structure along a sectional line I-I′ in FIG. 3C-1, in accordance with some embodiments. FIG. 3C-2 is a cross-sectional view illustrating the semiconductor device structure along a sectional line II-II′ in FIG. 3C-1, in accordance with some embodiments.

As shown in FIGS. 3C, 3C-1, and 3C-2, the steps of FIGS. 1C-2D are performed to form a semiconductor device structure 300, in accordance with some embodiments.

Processes and materials for forming the semiconductor device structure 300 may be similar to, or the same as, those for forming the semiconductor device structure 100 described above. Elements designated by the same or similar reference numbers as those in FIGS. 1A to 3C-2 have the same or similar structures and the materials. Therefore, the detailed descriptions thereof will not be repeated herein.

In accordance with some embodiments, semiconductor device structures and methods for forming the same are provided. The methods (for forming the semiconductor device structure) form an expansion film over fins and perform an annealing process to rotate the fins so as to increase the distance between the upper portions of the fins, which prevents the distance from becoming too small after a gate electrode layer is formed over the fins. Therefore, the expansion film and the annealing process facilitate in forming a metal gate stack, which fills the gaps between the fins, in a subsequent process. As a result, the formation of the expansion film and the annealing process improve the yield performance of the semiconductor device structure.

In accordance with some embodiments, a method for forming a semiconductor device structure is provided. The method includes forming an expansion film over a substrate. The substrate has a base portion, a first fin, and a second fin over the base portion. The method includes forming an isolation layer over the expansion film. The method includes annealing the expansion film, the substrate, and the isolation layer. A first average distance between a first upper portion of the first fin and a second upper portion of the second fin after the expansion film, the substrate, and the isolation layer are annealed is greater than a second average distance between the first upper portion of the first fin and the second upper portion of the second fin before the expansion film, the substrate, and the isolation layer are annealed. The method includes partially removing the isolation layer and the expansion film to expose the first upper portion of the first fin and the second upper portion of the second fin. The method includes forming a gate stack wrapping around the first upper portion of the first fin and the second upper portion of the second fin.

In accordance with some embodiments, a method for forming a semiconductor device structure is provided. The method includes forming an expansion film over a substrate. The substrate has a base portion, a first fin and a second fin over the base portion. The method includes forming an isolation layer over the expansion film. The method includes annealing the expansion film, the substrate, and the isolation layer. After the expansion film, the substrate, and the isolation layer are annealed, a first central axis of the first fin rotates in a first direction away from the second fin, a second central axis of the second fin rotates in a second direction away from the first fin in a cross-sectional view of the substrate, and a thickness of the expansion film is increased.

In accordance with some embodiments, a semiconductor device structure is provided. The semiconductor device structure includes a substrate having a base portion and a first fin over the base portion. The first fin has a first upper portion and a first lower portion, and a first central axis of the first upper portion is steeper than a second central axis of the first lower portion in a cross-sectional view of the substrate. The semiconductor device structure includes an expansion film conformally covering the first lower portion of the first fin and the base portion. The semiconductor device structure includes an isolation layer over the expansion film. A first density of the expansion film is greater than a second density of the isolation layer. The semiconductor device structure includes a gate stack wrapping around the first upper portion of the first fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming an expansion film over a substrate, wherein the substrate has a base portion, a first fin, and a second fin over the base portion;
forming an isolation layer over the expansion film;
annealing the expansion film, the substrate, and the isolation layer, wherein a first average distance between a first upper portion of the first fin and a second upper portion of the second fin after the expansion film, the substrate, and the isolation layer are annealed is greater than a second average distance between the first upper portion of the first fin and the second upper portion of the second fin before the expansion film, the substrate, and the isolation layer are annealed;
partially removing the isolation layer and the expansion film to expose the first upper portion of the first fin and the second upper portion of the second fin; and
forming a gate stack wrapping around the first upper portion of the first fin and the second upper portion of the second fin.

2. The method for forming the semiconductor device structure as claimed in claim 1, wherein after the expansion film, the substrate, and the isolation layer are annealed, a central axis of the first fin rotates in a direction away from the second fin in a cross-sectional view of the substrate.

3. The method for forming the semiconductor device structure as claimed in claim 1, wherein a third average distance between the first upper portion of the first fin and the second upper portion of the second fin after the gate stack is formed is less than the first average distance between the first upper portion of the first fin and the second upper portion of the second fin after the expansion film, the substrate, and the isolation layer are annealed and before the gate stack is formed.

4. The method for forming the semiconductor device structure as claimed in claim 1, wherein a first central axis of the first upper portion of the first fin is not parallel to a second central axis of the second upper portion of the second fin after the expansion film, the substrate, and the isolation layer are annealed and before the gate stack is formed.

5. The method for forming the semiconductor device structure as claimed in claim 4, wherein the first central axis of the first upper portion of the first fin is substantially parallel to the second central axis of the second upper portion of the second fin after the gate stack is formed.

6. The method for forming the semiconductor device structure as claimed in claim 1, wherein a first central axis of the first upper portion of the first fin is parallel to a second central axis of a lower portion of the first fin after the expansion film, the substrate, and the isolation layer are annealed and before the gate stack is formed.

7. The method for forming the semiconductor device structure as claimed in claim 6, wherein the first central axis of the first upper portion of the first fin is not parallel to the second central axis of the lower portion of the first fin after the gate stack is formed.

8. The method for forming the semiconductor device structure as claimed in claim 7, wherein the first central axis of the first upper portion of the first fin is steeper than the second central axis of the lower portion of the first fin after the gate stack is formed.

9. The method for forming the semiconductor device structure as claimed in claim 1, wherein the expansion film is conformally formed over the substrate.

10. The method for forming the semiconductor device structure as claimed in claim 1, wherein a first thickness of the expansion film after the expansion film, the substrate, and the isolation layer are annealed is greater than a second thickness of the expansion film before the expansion film, the substrate, and the isolation layer are annealed.

11. A method for forming a semiconductor device structure, comprising:
forming an expansion film over a substrate, wherein the substrate has a base portion, a first fin and a second fin over the base portion;
forming an isolation layer over the expansion film; and
annealing the expansion film, the substrate, and the isolation layer, wherein
after the expansion film, the substrate, and the isolation layer are annealed, a first central axis of the first fin rotates in a first direction away from the second fin, a second central axis of the second fin rotates in a second direction away from the first fin in a cross-sectional view of the substrate, and a thickness of the expansion film is increased.

12. The method for forming the semiconductor device structure as claimed in claim 11, further comprising:
partially removing the isolation layer and the expansion film to expose a first upper portion of the first fin and a second upper portion of the second fin; and
forming a gate stack wrapping around the first upper portion of the first fin and the second upper portion of the second fin.

13. The method for forming the semiconductor device structure as claimed in claim 11, wherein a first density of the expansion film is greater than a second density of the isolation layer.

14. The method for forming the semiconductor device structure as claimed in claim 11, wherein a first density of the expansion film before the expansion film, the substrate, and the isolation layer are annealed is greater than a second density of the expansion film after the expansion film, the substrate, and the isolation layer are annealed.

15. The method for forming the semiconductor device structure as claimed in claim 11, wherein the substrate further has a third fin between the first fin and the second fin, and
after the expansion film, the substrate, and the isolation layer are annealed, a third central axis of the third fin is steeper than the first central axis of the first fin in a cross-sectional view of the substrate.

16. A semiconductor device structure, comprising:
a substrate having a base portion and a first fin over the base portion, wherein the first fin has a first upper portion and a first lower portion, and a first central axis of the first upper portion is steeper than a second central axis of the first lower portion in a cross-sectional view of the substrate;
an expansion film conformally covering the first lower portion of the first fin and the base portion;
an isolation layer over the expansion film, wherein a first density of the expansion film is greater than a second density of the isolation layer; and
a gate stack wrapping around the first upper portion of the first fin.

17. The semiconductor device structure as claimed in claim 16, wherein a first angle between the second central axis of the first lower portion and a first top surface of the base portion is greater than 90°, and a second angle between the first central axis of the first upper portion and the first top surface of the base portion is about 90°.

18. The semiconductor device structure as claimed in claim 17, wherein the substrate further has a second fin over the base portion, the second fin has a second upper portion and a second lower portion,
a third angle between a third central axis of the second lower portion and the first top surface of the base portion is less than 90°, and a fourth angle between a fourth central axis of the second upper portion and the first top surface of the base portion is about 90°.

19. The semiconductor device structure as claimed in claim 16, further comprising:
a liner layer between the expansion film and the substrate, wherein the liner layer and the expansion film are made of different materials.

20. The semiconductor device structure as claimed in claim 16, wherein a first top surface of the expansion film is substantially level with a second top surface of the isolation layer.
